(19) United States
(12) Patent Application Publication
(10) Pub. No.: US 2006/0278893 A1
(43) Pub. Date: Dec. 14, 2006

(54) A hybrid bypolar-mos trench gate semiconductor device

(76) Inventor: Theodore J. Letavic, Putnam Valley, NY (US)

Correspondence Address: PHILIPS INTELLECTUAL PROPERTY & STANDARDS, P.O. BOX 3001, BRIARCLIFF MANOR, NY, 10510, US

(21) Appl. No.: 10/574,066

(22) PCT Filed: Sep. 27, 2004
(86) PCT No.: PCT/IB04/51881

§ 371 Date: Mar. 30, 2006

Related U.S. Application Data
(60) Provisional application No. 60/507,154, filed on Sep. 30, 2003.

(51) Int. Cl. H01L 31/00

(52) U.S. Cl. 257/197; 257/262

(57) ABSTRACT

An improved MOS device is disclosed that utilizes a voltage configuration shorting the body and the gate, and independently biasing the source. As a result, the device functions as a trench MOS device with an NPN bipolar transistor in parallel therewith, permitting a smaller size device to perform the DC-DC conversion only previously possible with conventional unipolar devices.

This invention relates to semiconductors, and more particularly, to an improved device that reduces the on resistance of a semiconductor device. The invention has particular applicability in trench-based devices, where the invention implements a parallel bipolar transistor with the MOS device to decrease on resistance, or equivalently substantially reduce the die size for the same level of total dissipation.

Metal Oxide Semiconductor trench devices (“TrenchMOS”) devices are well known in the art. A key figure of merit for such MOS devices when utilized to implement DC-DC converters is the size (area) of the device that is needed for a given total dissipation. In present state of the art, relatively large MOS devices are needed for a specified low dissipation to implement power supplies for high-end microprocessors.

It is an object of the invention to provide a hybrid MOS device that can provide a given dissipation at a significantly reduced size, thus resulting in a lower cost device.

It is also an object of the invention to provide a hybrid MOS device that can withstand high breakdown voltages, on the order of 200 volts.

The above and other problems of the prior art are overcome in accordance with the present invention relating to an improved hybrid MOS device. In accordance with the invention, a trench MOS type device having either single or multiple gate (field) oxide thicknesses is utilized in a hybrid mode, wherein one electrode is used for the gate and base, which are shorted together, and another electrode is used as both the source of an MOS device and the emitter of a bipolar device. In essence, the device is biased to function as both an MOS device as well as a bipolar device in parallel.

In a particular enhanced embodiment, the gate oxide thickness may be different along different lengths of the silicon trench thereof, so that higher breakdown voltages may be obtainable, and a more favorable tradeoff of specific-on resistance and total capacitance can be obtained.

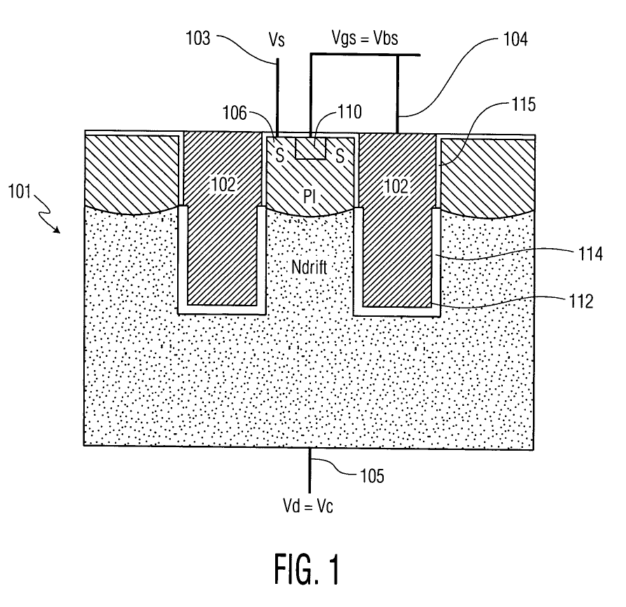

FIG. 1 depicts a cross sectional diagram of one exemplary embodiment of the invention.

FIG. 1 shows an exemplary embodiment of the present invention. A typical trench MOS device 101 includes a gate 102 and an electrode 103 and 104. Unlike conventional MOS devices designed for DC-DC conversion, the source region 106 and body region 110 are not shorted together and connected by a single electrode. Instead, electrode 104 shorts the body and gate regions, 110 and 102 respectively, as shown.

By shorting together the gate region 102 and body region 110 with electrode 104, and by correctly biasing the device as explained below, the source 106 will also serve as an emitter of a bipolar device, the body 110 will also serve as the base of the bipolar device, and the drain 105 will also serve as the collector of a bipolar device. In effect, by biasing the device correctly and causing a bipolar to device to be implemented within the MOS device, a hybrid device is achieved that can provide a much higher current drive capability Viewed alternatively, a hybrid construction designed for the same dissipation as the pure MOS device will have a much smaller area, resulting reduced costs.

As we now explain the operation of the device, we may use the terms body, gate, drain and source to refer to the appropriate regions, with the understanding that the regions double as the aforementioned regions of the bipolar transistor when the device is biased appropriately. In operation, a positive voltage is applied to electrode 104, biasing the body and gate regions 110 and 102 respectively. This creates a forward bias at these regions, causing the source 103 to serve as an emitter, and the body 110 to serve as the base of a bipolar device. The collector is denoted 105, the same region that serves as the drain of a bipolar device. At appropriate voltage (base current) levels, the voltage on the gate of the MOS device exceeds the threshold voltage, resulting in the addition of MOS current flow to the bipolar component.

This gate bias inverts the silicon on the mesa sidewall to form an MOS channel. Current flows from source/emitter region 102 through the base/body region 110 and along the trench sidewall 112. When current flows, the current is made up of both holes and electrons, providing a much higher current density and lowering on resistance with respect to conventional unipolar devices.

It is noted that the gate oxide thickness 114 adjacent to the Ndrift region is thicker than the gate oxide thickness 115 that is adjacent to the PI region. This thicker region 114 allows the device 101 to operate at higher breakdown voltages. For example, to operate up to 200 volts, region 114 would be approximately 10,000 A thick, while region 115 might only be 380 A. Alternatively, if the device were operated at lower voltages (<30V), only one thickness of approximately 380-1000 A would be needed. The thickness of the single-oxide device is generally determined by a tradeoff in voltage handling, on-resistance, and capacitance.

It is noted that although the electrodes 103 and 104 are shown side by side, they may actually be staggered in the third dimension in and out of the page. Additionally, the trench structure can be stripe, square, circular, hexagonal or any other geometry without the loss of the function, as viewed from the surface of the wafer.

The gate can be fabricated in polysilicon or any deposited metal. The fermi potential of the deposited gate can be used to adjust the threshold voltage of the MOS device, independent of the body (base) doping level. It is noted however, that optimizing the doping within the PI region in order to provide a particular threshold voltage for the MOS gate could have the effect of degrading the performance of the bipolar device. To avoid such a problem, and add an additional degree-of-freedom in device optimization, it may be desirable to form the gate electrode from _any deposited metal or refractory material (ie Al, Pt, Pd, TiW, silicides including CoSi2, TiSi2, etc), so that the bipolar transistor can be optimized independently of the channel of the MOS device. In this manner, the volume concentration of the base-body region can be selected to optimize base-transport and emitter injection efficiency, while minimizing effects on the threshold voltage and saturation characteristics of the MOS channel.

A double metal process flow is best for construction of the device to facilitate dense interconnect of the base-gate and source-emitter contact regions; although a single metal process flow can be used.

The above describes the preferred embodiment of the invention, although various modifications and additions will be apparent to those of skill in the art.

1. A hybrid MOS-bipolar device comprising a trench MOS device having at least source, gate, drain and body regions, the gate and base being shorted together and biased positively relative to the drain.

2. The hybrid MOS-bipolar device of claim 1 wherein said gate has a single oxide thickness of under 600 A.

3. The hybrid MOS-bipolar device of claim 1 wherein said gate has a multiple oxide thickness for formation of gate and field-oxide regions.

4. The hybrid MOS-bipolar device of claim 2 having a square trench geometry.

5. The hybrid MOS-bipolar device of claim 2 having a circular geometry.

6. A method of implementing a hybrid MOS-bipolar device having a source, body and gate, comprising shorting together body and gate of a trench MOS device and positively biasing the an electrode connected to the shorted body and gate.

7. The method of claim 6 wherein the gate oxide thickness varies along the length thereof.

8. The method of claim 7 wherein the gate oxide thickness varies by having two substantially discrete levels of thickness.

9. The method of claim 8 wherein said device has a PI region and an Ndrift region, and wherein a first gate oxide thickness is fabricated adjacent said PI region and a second and thicker gate oxide thickness is fabricated adjacent said Ndrift region.

10. A hybrid MOS-bipolar device comprising a PI region, an Ndrift region, a body, gate, drain and source, said device being configured with its base and gate shorted together, said device having a gate oxide thickness of a first value adjacent said PI region, and a gate oxide thickness of a second value adjacent said Ndrift region.

11. The hybrid MOS bipolar device of claim 10, wherein said gate and said body are positively biased.

12. A method of making a hybrid MOS-bipolar device comprising doping a PI region to optimize said region for said MOS device, and fabricating a gate electrode from to optimize a bipolar component of said hybrid MOS-bipolar device.

13. The method of claim 12 further comprising making a gate oxide thickness that varies along the length thereof.

14. The method of claim 13 wherein said gate oxide thickness is greater in a region adjacent said PI region than it is adjacent said Ndrift region.

15. The method of claim 14 wherein said device is constructed using a double metal process flow.

16. A hybrid bipolar-MOS device having a first region serving as a source and emitter, a second region serving as a body and a base, and a third region serving as a gate and base, the gate and base being shorted together and positively biased.

17. The hybrid bipolar-MOS device of claim 16 having a fourth region that serves as both a drain and a collector.

18. The hybrid bipolar-MOS device of claim 17 having a breakdown voltage of approximately 200 volts.

19. The hybrid bipolar-MOS device of claim 17 having a single gate oxide thickness of approximately 380-600 Angstoms.

20. The hybrid bipolar-MOS device of claim 17 having plural gate oxide thicknesses.

21. The hybrid MOS-bipolar device of claim 2 having a stripe geometry.
